(19) United States
(12) Patent Application Publication
(10) Pub. No.: US 2007/0117417 A1
(43) Pub. Date: May 24, 2007

(54) Pcb connector

(76) Inventor: Brenton O'Brien, Salisbury Heights (AU)

Correspondence Address: RATNERPRESTIA, P O BOX 980, VALLEY FORGE, PA, 19482-0980, US

(21) Appl. No.: 10/546,770

(22) PCT Filed: Feb. 17, 2004
(86) PCT No.: PCT/AU04/00178

§ 371 Date: Jun. 28, 2006

(30) Foreign Application Priority Data
Feb. 24, 2003 (AU) 2003900801

(51) Int. Cl. H05K 1/00

(52) U.S. Cl. 439/65

(57) ABSTRACT

A printed circuit board joining assembly adapted to join two printed circuit boards (1) together with an edge to edge alignment, said joining assembly having a clamping means (11, 13) holding at least one electrical conductor (3) so as to electrically connect an electrical conductor of a first of the boards with an electrical conductor of a second of the boards. A plurality of printed circuit boards with different functions may be joined in such a manner as to provide a complex electrical or electronic function.

### TECHNICAL FIELD

This invention relates to a method for constructing electrical and electronic devices using printed circuit boards and to an assembly when so constructed.

### BACKGROUND ART

The problem being addressed is to provide a joining method for printed circuit boards which can be helpful to developers in this field which can be better than those hitherto available.

### DISCLOSURE OF THE INVENTION

In one form of the invention, although this need not be the only or the broadest form, the invention may be said to reside in a method of constructing an electronic assembly including the steps of:
effecting for each of two printed circuit boards an electrical layout where there are at least two electrically conducting but electrically separated surfaces on a same respective side that are each connected to the circuits of each respective board and which are positioned to pass into or through a joining position of each respective board, then positioning the boards into a position with respective joining locations being coincident, effecting a clamping of a clamping member so as to engage with clamping force each board at or close to the joining location and having this also provide a physical joining thereby of the boards and having the clamping member effect also an electrical contact with each said electrically conducting surface.

The invention may also be said to reside in an electronic apparatus assembly having two printed circuit boards joined together with an edge to edge alignment by a joining assembly with a clamping means holding at least one electrical conductor so as to electrically connect an electrical conductor of a first of the boards with a conductor of a second of the boards.

In preference the joining assembly includes a non-conducting clamping member and one or more conductive tension members.

In preference the tension member is a bolt held in tension by a threaded member.

In preference the threaded member is a nut and the tension member is a bolt

In preference the head of the bolt forms an electrical connection between the conductive films on respective boards.

In preference there is provided a conductive surface on the top of the clamping member which connects one only conductive film on a board to one only conductive film on a second board when the joining assembly is in place.

In preference this conductive surface is a washer.

In preference in the alternative, this conductive surface is an integral part of the nut used to hold the bolt in position in the clamping member.

In preference this integral conductive surface is an annular structure with a diameter smaller than the width of the hexagonal part of the nut.

In preference the apparatus assembly is further characterised in that each of the printed circuit boards has a peripheral edge shape that intermeshes with the joining assembly facilitating alignment for a respective electrical conductor.

In preference this edge shape is a scallop adapted such that when a board is in edge to edge alignment with a second board also with such an edge shape, forms an opening adapted for the passage of the tension member.

In preference each scallop is surrounded by a contact pad of conductive film in electrical contact with one conductive track on a board, while being electrically insulated from all other tracks on the board.

In preference the contact pad and track is on at least one side of a board.

In preference the contact pad and conductive track provide for a functional connection to the electronic circuits of each respective board.

In preference said functional connections are provided in functional groups.

In preference there are provided groups of scallops with associated contact pads corresponding to said functional groups, distributed about the periphery of a board in such a manner as to allow the connection of the functional groups on a board with the corresponding functional groups on a second or subsequent board.

In preference a selected functional group may be associated with more than one group of edge scallops.

In preference the groups are located at regular spaced intervals along the periphery of the board. This provides that a plurality of boards can be joined together with the consistent location enabling a modular construction.

In preference the selected functional groups include a positive power connection, a negative power connection and a data connection.

The invention may also be said to reside in an electronic apparatus assembly having two printed circuit boards joined together with an edge to edge alignment by a joining assembly with a clamping means holding a plurality of electrical conductors so as to electrically connect each of the respective electrical conductors of a first of the boards with each of the respective electrical conductors of a second of the boards.

In preference each of the conductors provide for a functional connection to the electronic circuits of each respective board.

In preference the functional connections provide for a positive electrical rail function, a negative or ground electrical rail connection and an operating signal carrying conductor.

In preference in the alternative the boards are connected by the edges in a stacked configuration.

In preference, each of the boards is adapted to perform a single electronic or electrical function.

In preference, a plurality of boards with different functions may be joined in such a manner as to provide a complex electrical or electronic function.

In preference, the clamping means include an upper compression member a compression member, being a connection brick with locating lugs and bolt holes and nuts inserted into holes with an hexagonal shape of the hole serving to hold the nut captive when a bolt is inserted.

### BRIEF DESCRIPTION OF THE DRAWINGS

The invention will now be described with the assistance of drawings in which:

FIG. 1 shows a top view of a printed circuit board as used by the invention,

FIG. 2 shows a bottom view of a printed circuit board as used by the invention,

FIG. 3 shows a top view of the compression element,

FIG. 4 shows a bottom view of the compression element,

FIG. 5 shows an exploded view of two printed circuit boards joined in the manner of the invention,

FIG. 6 shows a top view of two printed circuit boards joined in the manner of the invention,

FIG. 7 shows a bottom view of two printed circuit boards joined in the manner of the invention,

FIG. 8 shows an exploded view of the method used to join printed circuit boards in a stacked configuration,

FIG. 9 shows a view of the connector in use to join printed circuit boards in a stacked configuration,

FIG. 10 shows a device built up from printed circuit boards in the manner of the invention. It is a line tracking robot, and

FIG. 11 shows an alternative embodiment of the connector.

### BEST MODE FOR CARRYING OUT THE INVENTION

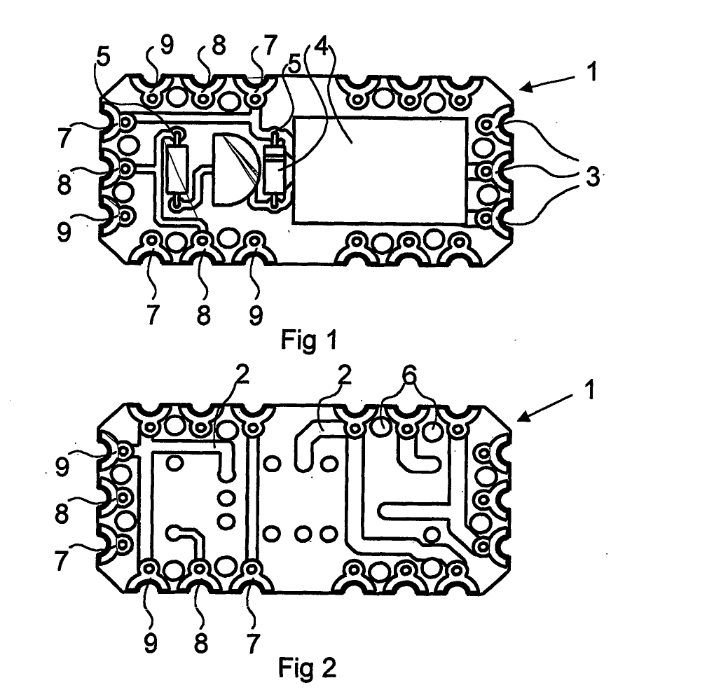

Referring to the drawings, in particular FIG. 1 and FIG. 2, there are circuit boards 1 with printed conductive tracks 2. These tracks provide electrical connection between component termination points 5 and contact pads 3. Electrical components 4 are attached to the board in such position as to be in electrical contact with appropriate tracks. The tracks and electrical components have been omitted from the remaining figures for the sake of clarity.

Locating holes 6 are drilled through the board.

The components and the electrical connections provided on each board are such as to provide a simple electrical or electronic function, which may be combined with other functions provided by other boards to provide a relatively complex function.

The board of FIG. 1 and FIG. 2 provides a relay function, with a positive supply rail 7, a ground rail 9 and a control signal conductor 8. The tracks providing these functional signals end on individual contact pads, surrounding scallops 21. It can be seen that this functional grouping 7, 8 and 9 for relay control appears at three points around the periphery of the board, allowing flexibility in the physical location of the co-operating board which provides the data input and power supply.

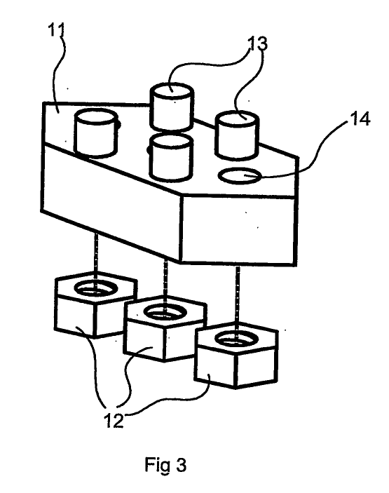

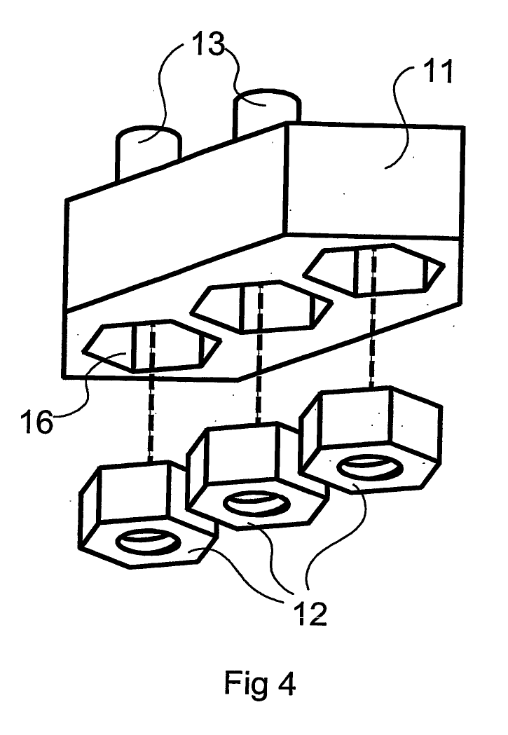

FIG. 3 and FIG. 4 show a compression member, being a connection brick 11 with locating lugs 13 and bolt holes 14. Nuts 12 are inserted into holes 16, with the hexagonal shape of the hole serving to hold the nut captive when a bolt is inserted.

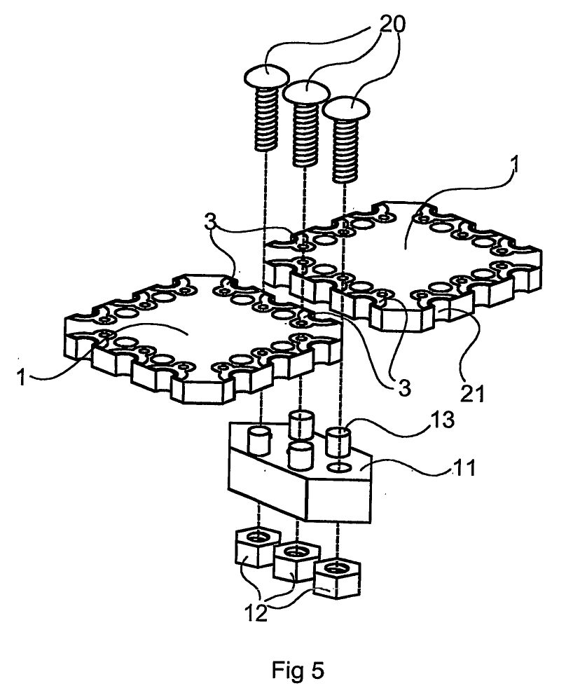

FIG. 5 shows an exploded view of the connection system in use. It can be seen that the scallops 21 cut in the side of the boards 1 coinciding with the contact pads 3 will, when the boards are brought together, form holes for the bolts 20. The bolts are metallic and form an electrical connection between the contact pads on the respective boards, thus electrically connecting tracks from the two boards. The locating lugs 13 are inserted into the holes 6 in the boards, providing correct alignment of the boards to ensure correct electrical connection. In order to avoid the possibility of incorrect electrical connection, the lugs are not locate a symmetrically about an axis bisecting the connector at right angles to the line of join of the boards. The lugs, and the corresponding holes on the two boards, are closer together on one side of such an axis than the other. Further, the lugs provide lateral support for the connection between the boards, resisting separation in the plane of the boards. In an alternative embodiment (not shown) a washer may be inserted between the connection brick and the board to provide electrical connection between contact pads on the lower sides of the respective boards.

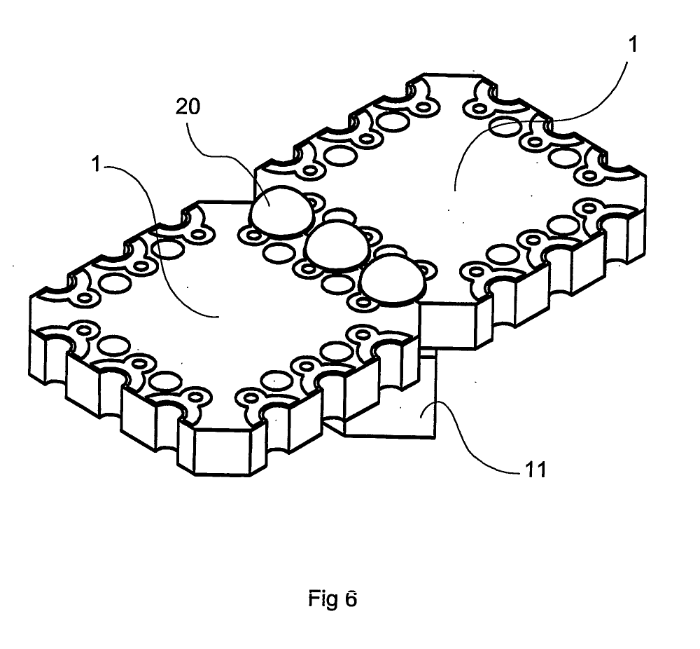

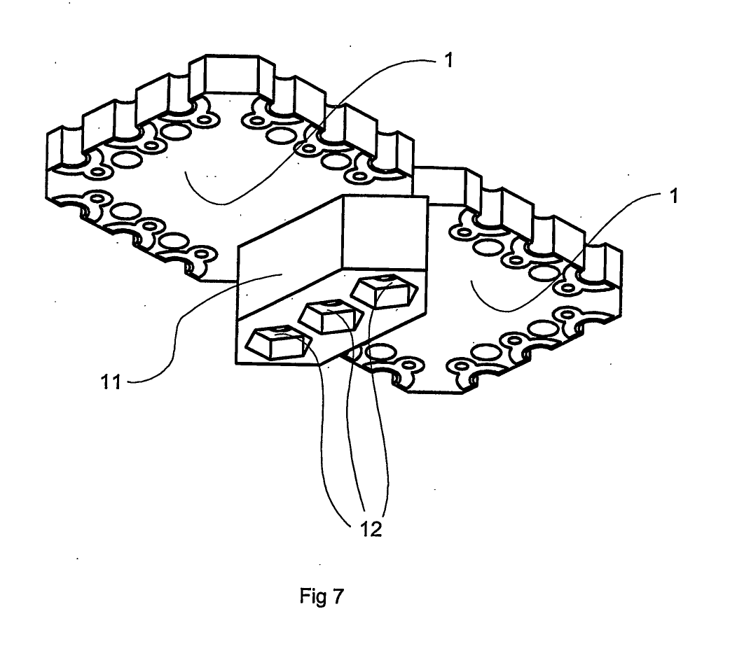

FIG. 6 and FIG. 7 show two boards connected in the manner of the invention. The bolts are screwed into the nuts held captive in the connector brick, holding the brick in compression against the boards. This compression, combined with the action of the locating lugs, serves to hold the boards in physical connection. Electrical connection between the boards is provided by the screw heads in contact with the contact pads on each board. This electrically connects the tracks and hence the components on the two boards to each other as required, the tracks and components having been omitted from the drawing for clarity.

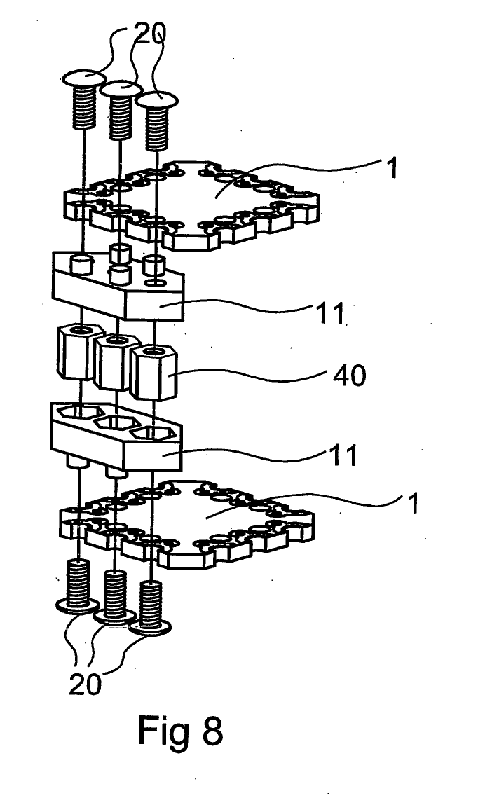

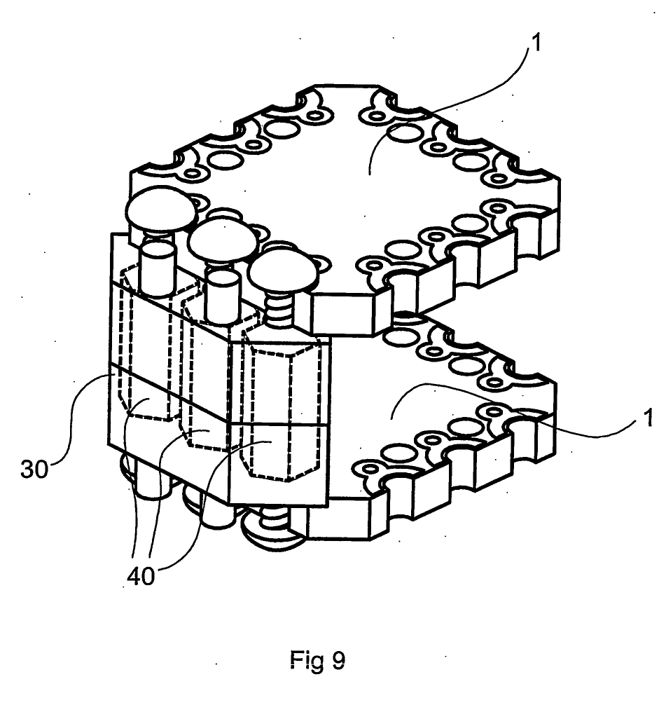

In some cases it may be necessary to join two boards in a stacked arrangement. FIG. 8 and FIG. 9 show how this may be achieved. The nuts for a connector bricks are replaced with longer threaded connectors 40. These threaded connectors are of such a length that when inserted into the nut holes of a connector brick, approximately half of the threaded connector remains exposed. The nut holes of another connector brick can then be located on the exposed ends, and both connector bricks fastened to separate printed circuit boards in the manner described above. The two boards are now physically joined in a stacked position, with the two connector bricks forming a compression unit 30 and the metallic bolts and the metallic threaded connector completing the electrical circuit between tracks on the boards.

Complex structures with complex electrical and electronic functions can be built up by joining printed circuit boards in the manner described. The boards provide the physical support structure for devices, while the electrical components provide the functional requirements.

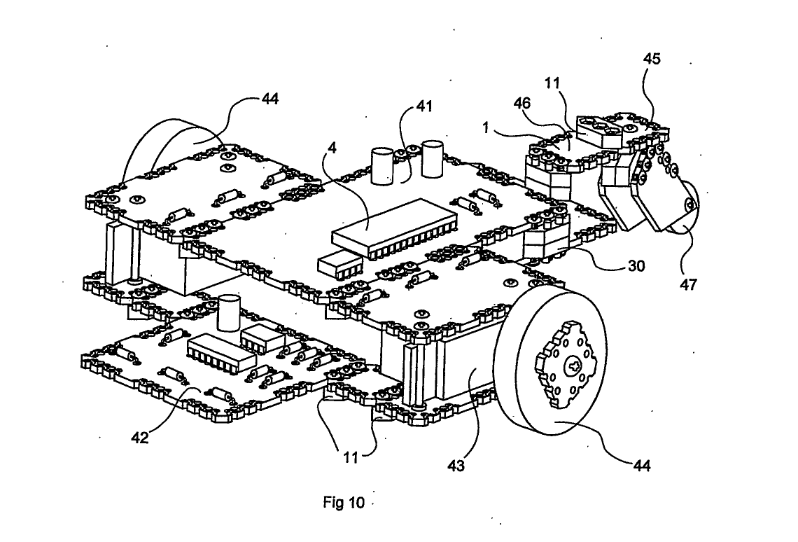

FIG. 10 shows a line tracking robot. Representative components are shown, but the printed tracks have been omitted for clarity.

A microprocessor is provided on a printed circuit board 41. This is connected electrically to board 42 which provides an optical sensor function. Servo-motor functions are provided by components on board 43, with ancillary electrical functions being provided by further printed circuit boards. The boards are physically connected in such a way as to form a chassis for the attachment of driven wheels 44 and tail wheel 47.

The optical sensor provides a signal to the microprocessor indicating the location of a line. The microprocessor then provides signals to the servomotors driving each driven wheel in order to keep the signal from the optical sensor within determined bounds. Hence the robot will “follow” a line.

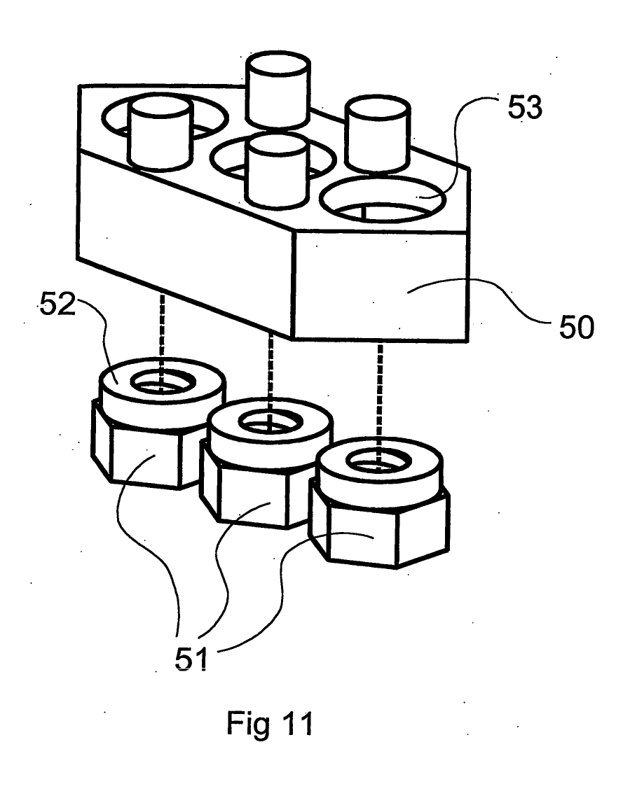

Boards 45 and 46 are connected in the same way as the other boards, but provide no electrical function, serving only as physical building blocks. In order to meet the physical requirements of forming the chassis, the stacking connection unit 30 is used as well as the planar connection of boards. An alternative form of the connector is shown in FIG. 11. The hexagonal nuts 51 are integrally formed with an annular section 52. The bolt holes 53 in the connector brick 50 are sufficiently large to allow the annular section of the nuts to protrude through and sit flush with the surface of the connector. The connector is then used in the same manner as for the previously described embodiment. The advantage is that both the bolt head and the annular section of the nut are held against the printed circuit board in operation, allowing for contact pads on both sides of the board to be in electrical connection. The intention of this description has been to illustrate and not to limit the invention, which can include variations and modifications falling within the scope and spirit of the invention.

1. A printed circuit board joining assembly adapted to join two printed circuit boards together with an edge to edge alignment said joining assembly having a clamping means holding at least one electrical conductor so as to electrically connect an electrical conductor of a first of the boards with an electrical conductor of a second of the boards.

2. The joining assembly of claim 1 wherein the assembly includes a non-conducting clamping member and one or more conductive tension members.

3. The joining assembly of claim 2 wherein the tension member is a bolt held in tension by a threaded member.

4. The joining assembly of claim 3 wherein the threaded member is a nut and the tension member is a bolt.

5. The joining assembly of claim 4 wherein the head of the bolt forms an electrical connection between the conductive films on respective boards.

6. The joining assembly of any one of claims 2-5 wherein there is provided a conductive surface on the top of the clamping member which connects one only conductive film on a board to one only conductive film on a second board when the joining assembly is in place.

7. The joining assembly of claim 6 wherein the conductive surface is a washer.

8. The joining assembly of claim 6 wherein the conductive surface is integrally formed with a nut used to hold the bolt in position in the clamping member.

9. The joining assembly of any one of claims 6-8 wherein the integral conductive surface is an annular structure with a diameter smaller than the width of a hexagonal part of the nut.

10. An electronic apparatus assembly having two printed circuit boards joined together with an edge to edge alignment by a joining assembly with a clamping means holding at least one electrical conductor so as to electrically connect an electrical conductor of a first of the boards with a conductor of a second of the boards, said clamping means including a non-conducting clamping member and one or more conductive tension members.

11. The apparatus assembly of claim 10 further characterized in that each of the printed circuit boards has a peripheral edge shape that intermeshes with the joining assembly facilitating alignment for a respective electrical conductor.

12. The apparatus assembly of claim 11 wherein the edge shape is a scallop adapted such that when a board is in edge to edge alignment with a second board also with such an edge shape, forms an opening adapted for the passage of the tension member.

13. The apparatus assembly of claim 12 wherein each scallop is surrounded by a contact pad of conductive film in electrical contact with one conductive track on a board, while being electrically insulated from all other tracks on the board.

14. The apparatus assembly of claim 13 wherein the contact pad and track is on at least one side of a board.

15. The apparatus assembly of claim 13 wherein the contact pad and conductive track provide for a functional connection to the electronic circuits of each respective board.

16. The apparatus assembly of claim 15 wherein said functional connections are provided in functional groups.

17. The apparatus assembly of claim 16 wherein there are provided groups of scallops with associated contact pads corresponding to said functional groups, distributed about the periphery of a board in such a manner as to allow the connection of the functional groups on a board with the corresponding functional groups on a second or subsequent board.

18. The apparatus assembly of claim 17 wherein a selected functional group is associated with more than one group of edge scallops.

19. The apparatus assembly of claim 17 wherein the functional groups are located at regular spaced intervals along the periphery of the board.

20. The apparatus assembly of claim 17 wherein the selected functional groups include a positive power connection, a negative power connection and a data connection.

21. A method of constructing an electronic assembly including the steps of:
effecting for each of two printed circuit boards an electrical layout where there are at least two electrically conducting but electrically separated surfaces on a same respective side that are each connected to the circuits of each respective board and which are positioned to pass into or through a joining position of each respective board, then positioning the boards into a position with respective joining locations being coincident, effecting a clamping of a clamping member so as to engage with clamping force each board at or close to the joining location and having this also provide a physical joining thereby of the boards and having the clamping member effect also an electrical contact with each said electrically conducting surface.

22. An electronic apparatus assembly having two printed circuit boards joined together with an edge to edge alignment by a joining assembly with a clamping means holding a plurality of electrical conductors so as to electrically connect each of the respective electrical conductors of a first of the boards with each of the respective electrical conductors of a second of the boards, the clamping means including an upper compression member said compression member, being a connection brick with locating lugs and bolt holes and nuts inserted into holes with an hexagonal shape of the hole serving to hold the nut captive when a bolt is inserted.

23. An electronic apparatus assembly as in claim 22 wherein each of the conductors provide for a functional connection to the electronic circuits of each respective board.

24. An electronic apparatus assembly as in claim 23 wherein the functional connections provide for a positive electrical rail function, a negative or ground electrical rail connection and an operating signal carrying conductor.

25. An electronic apparatus assembly as in any one of claims 22-24 wherein the boards are connected by the edges in a stacked configuration.

26. An electronic apparatus assembly as in any one of claims 22-24 wherein each of the boards is adapted to perform a single electronic or electrical function.

27. An electronic apparatus assembly as in claim 26 wherein a plurality of printed circuit boards with different functions are joined in such a manner as to provide a complex electrical or electronic function.

28. An electronic apparatus assembly substantially as described with respect to any one of the embodiments in the specification with reference to and as illustrated by the accompanying illustrations with respect to that embodiment.

29. A method of constructing an electronic assembly substantially as described with respect to any one of the embodiments in the specification with reference to and as illustrated by the accompanying illustrations with respect to that embodiment.
